(19) United States
(12) Patent Application Publication
(10) Pub. No.: US 2024/0002599 A1
(43) Pub. Date: Jan. 4, 2024

(54) PHOTOSENSITIVE RESIN COMPOSITION, PHOTOSENSITIVE MATERIAL COMPRISING SAME, BLACK MATRIX COMPRISING SAME, AND ELECTRONIC ELEMENT COMPRISING SAME

(71) Applicant: LG CHEM, LTD., Seoul (KR)

(72) Inventors: Seongho JEON, Daejeon (KR); Kyouhyun NAM, Daejeon (KR); Hyunmin PARK, Daejeon (KR)

(73) Assignee: LG CHEM, LTD., Seoul (KR)

(21) Appl. No.: 18/251,849

(22) PCT Filed: Nov. 9, 2021
(86) PCT No.: PCT/KR2021/016205

§ 371 Date: May 4, 2023

(30) Foreign Application Priority Data
Nov. 9, 2020 (KR) 10-2020-0148439

(51) Int. Cl. C08G 73/10

(52) U.S. Cl. CPC C08G 73/1028

(57) ABSTRACT

The present disclosure relates to a photosensitive resin composition, a photosensitive material including the same, a black matrix including the same, and an electronic device including the same.

This application is a 35 U.S.C. 371 National Phase Entry Application from PCT/KR2021/016205 filed on Nov. 9, 2021, which claims priority to and the benefits of Korean Patent Application No. 10-2020-0148439, filed with the Korean Intellectual Property Office on Nov. 9, 2020, the entire contents of which are incorporated herein by reference.

### TECHNICAL FIELD

The present disclosure relates to a photosensitive resin composition, a photosensitive material including the same, a black matrix including the same, and an electronic device including the same.

### BACKGROUND OF DISCLOSURE

A grid black pattern referred to as a black matrix is generally disposed between color pixels of a color filter with the purpose of enhancing contrast. In an existing black matrix, a method of depositing and etching chromium (Cr) on an entire glass substrate as a pigment to form a pattern may be used, however, high costs are required in the process, and a problem of high reflectivity of the chromium, a problem of environmental pollution caused by the chromium waste solution and the like have occurred. Due to such reasons, studies on a black matrix using a pigment dispersion method capable of micro-processing have been actively conducted, and studies on preparing a black composition with coloring pigments other than carbon black have also been conducted. However, coloring pigments other than carbon black have a weak light-shielding property, and therefore, a mixed amount thereof needs to be increased to an extremely large amount, and as a result, problems of difficult handling caused by an increase in viscosity of the composition, or significantly decreasing strength of a formed film or adhesion for a substrate have occurred.

Accordingly, studies on a photosensitive resin composition having excellent pattern adhesion, process properties and the like have been required.

In addition, excellent mechanical properties and high heat resistance are required for an interlayer insulating film or surface protection film of a semiconductor device, and a polyimide-based binder resin having excellent properties has been used. A negative-type photosensitive polyimide has relatively superior mechanical properties, but is difficult to obtain high resolution. A positive-type photosensitive polyimide is capable of obtaining relatively high resolution, but is difficult to satisfy mechanical properties.

Accordingly, development of a photosensitive material satisfying both high resolution and mechanical properties has been required.

### DISCLOSURE

### Brief Summary for Disclosure

The present disclosure is directed to providing a photosensitive resin composition, a photosensitive material including the same, a black matrix including the same, and an electronic device including the same.

One embodiment of the present disclosure provides a photosensitive resin composition including an alkali-soluble polyimide resin including repeating units represented by the following Chemical Formulae 1 to 3, and a solvent.

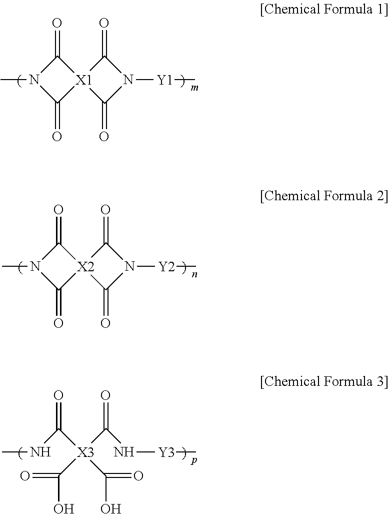

In Chemical Formulae 1 to 3,
X1 to X3 are the same as or different from each other, and each independently a tetravalent organic group,
Y1 to Y3 are the same as or different from each other, and each independently a divalent organic group, and
Y2 includes a group represented by the following Chemical Formula A,

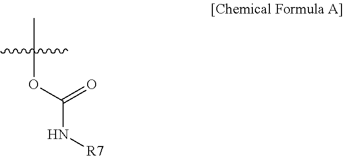

in Chemical Formula A,
R7 is hydrogen; deuterium; a hydroxyl group; a halogen group; a nitro group; a nitrile group; a substituted or unsubstituted alkyl group; a substituted or unsubstituted alkenyl group; a substituted or unsubstituted alkynyl group; a substituted or unsubstituted alkoxy group; a substituted or unsubstituted aryloxy group; a substituted or unsubstituted cycloalkyl group; a substituted or unsubstituted aryl group; a substituted or unsubstituted heterocyclic group; or a photopolymerizable unsaturated group,

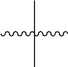

means a site bonding to Y2 of Chemical Formula 2, and
m to p are each independently an integer of 1 to 500.

In the photosensitive resin composition provided in one embodiment of the present disclosure, as for m to p of Chemical Formulae 1 to 3, p/(m+n+p) is from 0.03 to 0.15.

One embodiment of the present disclosure provides a black matrix including the photosensitive resin composition described above.

One embodiment of the present disclosure provides an electronic device including the black matrix.

### Advantageous Effects

A photosensitive resin composition and a black matrix including the same according to one embodiment of the present disclosure have enhanced heat resistance properties.

A photosensitive resin composition and a black matrix including the same according to one embodiment of the present disclosure have a reduced amount of out-gas generated in a process such as development.

According to one embodiment of the present disclosure, an electronic device including a black matrix having excellent heat resistance or having a small amount of out-gas generated in a process such as development can be provided.

### DETAILED DESCRIPTION FOR DISCLOSURE

Hereinafter, the present disclosure will be described in detail.

One embodiment of the present disclosure provides a photosensitive resin composition including an alkali-soluble polyimide resin including repeating units represented by the following Chemical Formulae 1 to 3, and a solvent.

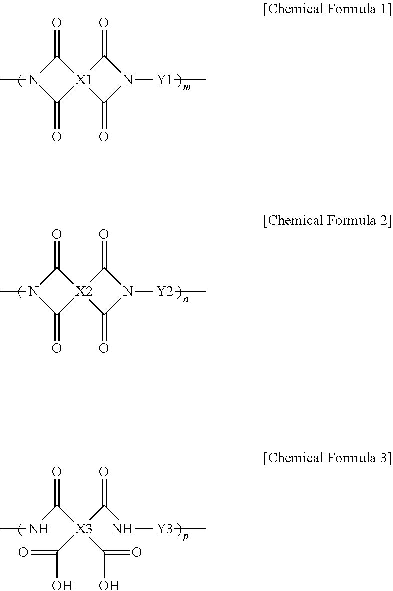

In Chemical Formulae 1 to 3,
X1 to X3 are the same as or different from each other, and each independently a tetravalent organic group,
Y1 to Y3 are the same as or different from each other, and each independently a divalent organic group, and
Y2 includes a group represented by the following Chemical Formula A,

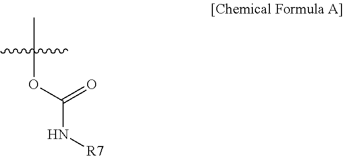

in Chemical Formula A,
R7 is hydrogen; deuterium; a hydroxyl group; a halogen group; a nitro group; a nitrile group; a substituted or unsubstituted alkyl group; a substituted or unsubstituted alkenyl group; a substituted or unsubstituted alkynyl group; a substituted or unsubstituted alkoxy group; a substituted or unsubstituted aryloxy group; a substituted or unsubstituted cycloalkyl group; a substituted or unsubstituted aryl group; a substituted or unsubstituted heterocyclic group; or a photopolymerizable unsaturated group,

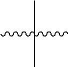

means a site bonding to Y2 of Chemical Formula 2, and
m to p are each independently an integer of 1 to 500.

The photosensitive resin composition including the alkali-soluble polyimide resin according to one embodiment of the present disclosure has excellent adhesion for a substrate used in a display apparatus such as an organic light emitting diode.

In addition, the photosensitive resin composition including the alkali-soluble polyimide resin according to one embodiment of the present disclosure has excellent mechanical properties such as heat resistance or chemical resistance. Accordingly, side reactions that proceeds during the process is reduced, which reduces an amount of out-gas generated in the process such as development.

The photosensitive resin composition including the alkali-soluble polyimide resin having a closed-ring structure (imide structure) and a non-closed-ring structure in a specific ratio according to one embodiment of the present disclosure prevents swelling or a decrease in solubility caused by the ring closure of the side chain during development.

In the present disclosure, a description of a certain member being placed “on” another member includes not only a case of the certain member being in contact with the another member but a case of still another member being present between the two members.

In the present disclosure, a description of a certain part “including” certain constituents means capable of further including other constituents, and does not exclude other constituents unless particularly stated on the contrary.

Unless defined otherwise in the present disclosure, all technical and scientific terms used in the present disclosure have the same meanings as terms commonly understood by those skilled in the art. Although methods and materials similar or equivalent to those described in the present disclosure may be used in implementing or experimenting embodiments of the present disclosure, suitable methods and materials are described later. All publications, patent applications, patents and other reference documents mentioned in the present disclosure are incorporated by reference in the present disclosure as a whole, and when conflicting, the present disclosure including definitions has priority unless specific passage is mentioned. Furthermore, materials, methods and examples are for illustrative purposes only, and not to limit the present disclosure.

Examples of the substituents in the present disclosure are described below, however, the substituents are not limited thereto.

In the present disclosure,

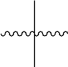

means a linked site.

In the present disclosure, the term “substitution” means a hydrogen atom bonding to a carbon atom of a compound being changed to another substituent, and the position of substitution is not limited as long as it is a position at which the hydrogen atom is substituted, that is, a position at which a substituent is capable of substituting, and when two or more substituents substitute, the two or more substituents may be the same as or different from each other.

In the present disclosure, the term “substituted or unsubstituted” means being substituted with one or more substituents selected from the group consisting of deuterium; a halogen group; a cyano group; an alkyl group; a cycloalkyl group; an alkoxy group; an aryloxy group; an aryl group; and a heterocyclic group, or being substituted with a substituent linking two or more substituents among the substituents illustrated above, or having no substituents.

In the present disclosure, the halogen group is a fluoro group (—F), a chloro group (—Cl), a bromo group (—Br) or an iodo group (—I).

In the present disclosure, the alkyl group may be linear or branched, and although not particularly limited thereto, the number of carbon atoms may be from 1 to 20. According to another embodiment, the number of carbon atoms of the alkyl group is from 1 to 10. Specific examples of the alkyl group may include a methyl group, an ethyl group, an n-propyl group, an isopropyl group, an n-butyl group, an isobutyl group, a tert-butyl group, an n-pentyl group, an n-hexyl group, an n-heptyl group and the like, but are not limited thereto.

In the present disclosure, the alkenyl group includes linear or branched having 2 to 60 carbon atoms, and may be further substituted with other substituents. The number of carbon atoms of the alkenyl group may be from 2 to 60, specifically from 2 to 40 and more specifically from 2 to 20. Specific examples thereof may include a vinyl group, a 1-propenyl group, an isopropenyl group, a 1-butenyl group, a 2-butenyl group, a 3-butenyl group and the like, but are not limited thereto.

In the present disclosure, the alkynyl group includes linear or branched having 2 to 60 carbon atoms, and may be further substituted with other substituents. The number of carbon atoms of the alkynyl group may be from 2 to 60, specifically from 2 to 40 and more specifically from 2 to 20.

In the present disclosure, the cycloalkyl group may include monocyclic or polycyclic having 3 to 60 carbon atoms, and may be further substituted with other substituents. Herein, the polycyclic means a group in which the cycloalkyl group is directly linked or fused to other cyclic groups. Herein, the other cyclic group may be a cycloalkyl group, but may also be a different type of cyclic group, for example, a heterocycloalkyl group, an aryl group, a heteroaryl group or the like. The number of carbon atoms of the cycloalkyl group may be from 3 to 60, specifically 3 to 40 and more specifically 5 to 20. Specific examples thereof may include a cyclopropyl group, a cyclobutyl group, a cyclopentyl group, a 3-methylcyclopentyl group and the like, but are not limited thereto.

In the present disclosure, the alkoxy group may be linear or branched. The number of carbon atoms of the alkoxy group is not particularly limited, but may be from 1 to 20. Specific examples of the alkoxy group may include a methoxy group, an ethoxy group, an n-propoxy group, an n-butoxy group, a tert-butoxy group, an n-pentyloxy group, an n-hexyloxy group, an n-octyloxy group, an n-nonyloxy group, an n-decyloxy group and the like, but are not limited thereto.

In the present disclosure, the aryloxy group means —ORaryloxy, and the Raryloxy means an aryl group.

In the present disclosure, the aryl group is not particularly limited, but may have 6 to 60 carbon atoms, and may be a monocyclic aryl group or a polycyclic aryl group. According to one embodiment, the number of carbon atoms of the aryl group is from 6 to 30. According to one embodiment, the number of carbon atoms of the aryl group is from 6 to 20. When the aryl group is a monocyclic aryl group, examples thereof may include a phenyl group, a biphenyl group, a terphenyl group and the like, but are not limited thereto. Examples of the polycyclic aryl group may include a naphthyl group, an anthracenyl group, a phenanthrenyl group, a pyrenyl group, a perylenyl group, a triphenylenyl group, a chrysenyl group, a fluorenyl group and the like, but are not limited thereto.

In the present disclosure, the fluorenyl group may be substituted, and two substituents may bond to each other to form a spiro structure. When the fluorenyl group is substituted, a spirofluorenyl group such as

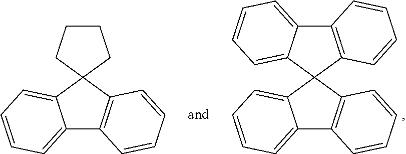

a substituted fluorenyl group such as

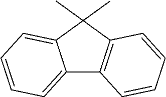

(9,9-dimethylfluorenyl group) and

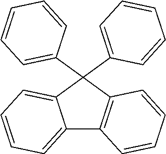 [SMILES: c1ccc(C2(c3ccccc3)c3ccccc3-c3ccccc32)cc1]

(9,9-diphenylfluorenyl group), and the like may be included. However, the structure is not limited thereto.

In the present disclosure, the heteroaryl group is an aromatic cyclic group including one or more of N, O, P, S, Si and Se as a heteroatom, and although not particularly limited thereto, the number of carbon atoms may be from 2 to 60. According to one embodiment, the number of carbon atoms of the heteroaryl group is from 2 to 30. Examples of the heteroaryl group may include a pyridine group, a pyrrole group, a pyrimidine group, a pyridazine group, a furan group, a thiophene group, a benzothiophene group, a benzofuran group, a dibenzothiophene group, a dibenzofuran group and the like, but are not limited thereto.

In the present disclosure, a “monomer” means a unit compound that a compound may be converted to a polymer compound by a polymerization reaction, and may be a repeating unit in a polymer or a copolymer. Specifically, this means that the corresponding compound is polymerized and bonds in a polymer, and all or a part of two or more substituents are removed from the structure of the corresponding compound, and at the positions, radicals for bonding with other units of the polymer are located. Herein, the corresponding compound may be polymerized in any order and included in the polymer in a bonded state.

In the present disclosure, a description of a molecular weight means a weight average molecular weight unless particularly defined otherwise.

The weight average molecular weight is one of average molecular weights in which molecular weights are not uniform and a molecular weight of a certain polymer material is used as a reference, and is a value obtained by averaging molecular weights of component molecular species of a polymer compound having molecular weight distribution by a weight fraction.

The weight average molecular weight may be measured using a gel permeation chromatography (GPC) method. In a process of measuring a weight average molecular weight using a GPC method, commonly known analyzers, detectors such as a refractive index detector, and columns for analysis may be used, and commonly applied temperature conditions, solvents, solvent rates and the like may be applied. As a specific example of the measurement condition, Polymer Laboratories PLgel MIX-B 300 mm length column and Waters PL-GPC220 device are used, an evaluation temperature is 160° C., 1,2,4-trichlorobenzene is used as a solvent, a flow rate is 1 mL/min, a sample is prepared to have a concentration of 10 mg/10 mL and supplied in an amount of 200 μL, and an Mw value may be obtained using a calibration curve formed using a polystyrene standard. As the molecular weight of the polystyrene standard, 9 types of 2,000/10,000/30,000/70,000/200,000/700,000/2,000,000/4,000,000/10,000,000 are used.

In the present disclosure, the acryloyl group is not particularly limited, but preferably has 3 to 40 carbon atoms, and the descriptions on the acryloyl group may be applied to an acrylate group. In addition, examples of the acryloyl group or the acrylate group may include methyl acrylate, ethyl acrylate, methacrylate, 3-(acryloyloxy)propyl methacrylate and the like, but are not limited thereto.

In the present disclosure, the unsaturated group in the photopolymerizable unsaturated group means a functional group, a substituent or an organic group including an unsaturated bond. The unsaturated bond refers to a state in which another element may additionally bond to carbon, and may specifically mean a double or triple bond. Specific examples of the functional group, the substituent or the organic group having an unsaturated bond may include an unsaturated double bond functional group or an unsaturated triple bond functional group such as a propargyl group, and among these, a conjugated vinyl group, an acryloyl group, a methacryloyl group or the like may be included. In addition, the number of the functional groups included may be from 1 to 4 in terms of stability, and the functional groups may each be the same as or different from each other. In addition, the photopolymerizable in the photopolymerizable unsaturated group may mean a property of polymerizing by an action of a photopolymerization initiator or light.

In the present disclosure, the alkali-soluble means a property of increasing solubility for an alkali material (developing solution and the like) by being dissociated by an acid. For example, an alkali-soluble resin and an alkali-soluble group respectively mean a resin and a substituent having increased solubility for an alkali developing solution by being dissociated by an acid. The alkali-soluble group includes an alkali-soluble hydroxyl group. Examples of such an alkali-soluble hydroxyl group may include a phenolic hydroxyl group, but are not limited thereto.

In the present disclosure, a content of A1 with respect to A may be expressed such that “a content of A1 is from 1 parts by weight to 10 parts by weight with respect to A”, “A1 is included in 1 parts by weight to 10 parts by weight with respect to A” or the like, however, the expression is not limited thereto.

According to one embodiment of the present disclosure, the photosensitive resin composition includes at least one of a binder resin and a coloring agent.

According to one embodiment of the present disclosure, the photosensitive resin composition includes a binder resin.

According to one embodiment of the present disclosure, the photosensitive resin composition includes a coloring agent.

According to one embodiment of the present disclosure, at least one of the binder resin and the coloring agent includes the alkali-soluble polyimide resin.

According to one embodiment of the present disclosure, the binder resin includes the alkali-soluble polyimide resin.

According to one embodiment of the present disclosure, the binder resin is the alkali-soluble polyimide resin according to one embodiment of the present disclosure.

According to one embodiment of the present disclosure, the binder resin may be included in 15 parts by weight to 50 parts by weight; or in 20 parts by weight to 45 parts by weight with respect to 100 parts by weight of a solid content of the photosensitive resin composition (solid content excluding solvent in the photosensitive resin composition). As preferred one example, the binder resin may be included in 35 parts by weight to 45 parts by weight with respect to 100 parts by weight of a solid content of the photosensitive resin composition (solid content excluding solvent in the photosensitive resin composition), however, the content is not limited to the examples.

In the present disclosure, the binder resin may further include, in addition to the alkali-soluble polyimide resin including the repeating units represented by Chemical Formulae 1 to 3, a binder resin generally used in the art.

According to one embodiment of the present disclosure, the coloring agent includes the alkali-soluble polyimide resin.

According to one embodiment of the present disclosure, the coloring agent is the alkali-soluble polyimide resin according to one embodiment of the present disclosure.

According to one embodiment of the present disclosure, the coloring agent may be included in 14 parts by weight to 50 parts by weight; or in 20 parts by weight to 45 parts by weight with respect to 100 parts by weight of a solid content of the photosensitive resin composition (solid content excluding solvent in the photosensitive resin composition). As preferred one example, the coloring agent may be included in 25 parts by weight to 35 parts by weight with respect to 100 parts by weight of a solid content of the photosensitive resin composition (solid content excluding solvent in the photosensitive resin composition), however, the content is not limited to the examples.

According to one embodiment of the present disclosure, a content of the binder resin is from 15 parts by weight to 50 parts by weight, and a content of the coloring agent is from 14 parts by weight to 50 parts by weight with respect to 100 parts by weight of a solid content of the photosensitive resin composition (solid content excluding solvent in the photosensitive resin composition).

According to one embodiment of the present disclosure, a content of the binder resin is from 35 parts by weight to 45 parts by weight, and a content of the coloring agent is from 25 parts by weight to 35 parts by weight with respect to 100 parts by weight of a solid content of the photosensitive resin composition (solid content excluding solvent in the photosensitive resin composition).

According to one embodiment of the present disclosure, the photosensitive resin composition includes at least one of a binder resin and a coloring agent, and at least one of the binder resin and the coloring agent includes the alkali-soluble polyimide resin.

According to one embodiment of the present disclosure, the photosensitive resin composition includes a binder resin and a coloring agent, and the binder resin and the coloring agent include the alkali-soluble polyimide resin.

According to one embodiment of the present disclosure, the photosensitive resin composition includes a binder resin and a coloring agent, and the binder resin and the coloring agent are the alkali-soluble polyimide resin according to one embodiment of the present disclosure.

By both the binder resin and the coloring agent included in the photosensitive resin composition according to one embodiment of the present disclosure including the alkali-soluble polyimide resin including the repeating units represented by Chemical Formulae 1 to 3, heat resistance of the photosensitive resin composition may greatly increase. Specifically, heat resistance involving in adhesive strength with a substrate increases by including the polyimide resin, a resin with high heat resistance having insoluble and infusible properties, in the binder resin, and the polyimide resin included in the coloring agent increases heat resistance of a deposited material itself remaining after development and etching.

According to one embodiment of the present disclosure, the coloring agent includes a pigment; and at least one of a dispersant and a binder for dispersion.

According to one embodiment of the present disclosure, the coloring agent includes a pigment and a dispersant.

According to one embodiment of the present disclosure, the coloring agent includes a pigment and a binder for dispersion.

According to one embodiment of the present disclosure, the coloring agent includes a pigment, a dispersant and a binder for dispersion.

According to one embodiment of the present disclosure, at least one of the dispersant and the binder for dispersion includes the alkali-soluble polyimide resin.

According to one embodiment of the present disclosure, the dispersant includes the alkali-soluble polyimide resin.

According to one embodiment of the present disclosure, the dispersant is the alkali-soluble polyimide resin according to one embodiment of the present disclosure.

According to one embodiment of the present disclosure, the binder for dispersion includes the alkali-soluble polyimide resin.

According to one embodiment of the present disclosure, the binder for dispersion is the alkali-soluble polyimide resin according to one embodiment of the present disclosure.

According to one embodiment of the present disclosure, the coloring agent includes a dispersant including the alkali-soluble polyimide resin including the repeating units represented by Chemical Formulae 1 to 3 and a binder for dispersion including the alkali-soluble polyimide resin including the repeating units represented by Chemical Formulae 1 to 3.

According to preferred one embodiment of the present disclosure, the coloring agent includes a pigment; a dispersant including the alkali-soluble polyimide resin including the repeating units represented by Chemical Formulae 1 to 3; and a binder for dispersion including the alkali-soluble polyimide resin including the repeating units represented by Chemical Formulae 1 to 3.

According to one embodiment of the present disclosure, a content of the pigment is from 10 parts by weight to 50 parts by weight; or from 15 parts by weight to 40 parts by weight with respect to 100 parts by weight of a solid content of the photosensitive resin composition. As preferred one example, a content of the pigment is from 20 parts by weight to 30 parts by weight with respect to 100 parts by weight of a solid content of the photosensitive resin composition.

According to one embodiment of the present disclosure, a content of the dispersant is from 2 parts by weight to 15 parts by weight; or from 2 parts by weight to 10 parts by weight with respect to 100 parts by weight of a solid content of the photosensitive resin composition. As preferred one example, a content of the dispersant is from 3 parts by weight to 6 parts by weight with respect to 100 parts by weight of a solid content of the photosensitive resin composition.

According to one embodiment of the present disclosure, a content of the binder for dispersion is from 2 parts by weight to 15 parts by weight; or from 2 parts by weight to 10 parts by weight with respect to 100 parts by weight of a solid content of the photosensitive resin composition. As preferred one example, a content of the binder for dispersion is from 3 parts by weight to 6 parts by weight with respect to 100 parts by weight of a solid content of the photosensitive resin composition.

According to one embodiment of the present disclosure, a content of the pigment is from 10 parts by weight to 50 parts by weight, a content of the dispersant is from 2 parts by weight to 15 parts by weight, and a content of the binder for dispersion is from 2 parts by weight to 15 parts by weight, with respect to 100 parts by weight of the coloring agent. As preferred one example, the pigment, the dispersant and the binder for dispersion may be respectively included in 24 parts by weight, 4.8 parts by weight and 4.8 parts by weight with respect to 100 parts by weight of a solid content of the photosensitive resin composition, however, the content is not limited thereto.

As described above, when the pigment is included in the above-mentioned range, high color reproduction is obtained, and increased luminance is obtained as well. When the dispersant and the binder for dispersion are included in the above-mentioned ranges, excellent developability is obtained, or surface smoothness may be improved by improving crosslinking properties.

The pigment exhibits visibility or hiding power, and as the pigment, red, blue, green, yellow and block pigments, and the like, may be used. Specific examples of such a pigment may include carmine 6B (C.I. 12490), phthalocyanine green (C.I. 74260), phthalocyanine blue (C.I. 74160), Mitsubishi carbon black MA100, perylene black (BASF K0084. K0086), cyanine black, linol yellow (C.I. 21090), linol yellow GRO (C.I. 21090), benzidine yellow 4T-564D, Mitsubishi carbon black MA-40, Victoria pure blue (C.I. 42595), C.I. PIGMENT RED97, 122, 149, 168, 177, 180, 192, 215, C.I. PIGMENT GREEN 7, 36, C.I. PIGMENT 15:1, 15:4, 15:6, 22, 60, 64, C.I. PIGMENT 83, 139 C.I. PIGMENT VIOLET 23 and the like, and, in addition thereto, white pigments, fluorescent pigments and the like may also be used. However, the pigment is not limited thereto.

According to one embodiment of the present disclosure, the pigment includes carbon black alone, or a mixture of carbon black and two or more coloring pigments. Specific examples of the carbon black may include Sisto 5HIISAF-HS, Sisto KH, Sisto 3HHAF-HS, Sisto NH, Sisto 3M, Sisto 300HAF-LS, Sisto 116HMMAF-HS, Sisto 116MAF, Sisto FMFEF-HS, Sisto SOFEF, Sisto VGPF, Sisto SVHSRF-HS, and Sisto SSRF of Tokai Carbon Co., Ltd.; Diagram black II Diagram black N339, Diagram black SH, Diagram black H, Diagram LH, Diagram HA, Diagram SF, Diagram N550M, Diagram M, Diagram E, Diagram G, Diagram R, Diagram N760M, Diagram LR, #2700, #2600, #2400, #2350, #2300, #2200, #1000, #980, #900, MCF88, #52, #50, #47, #45, #45L, #25, #CF9, #95, #3030, #3050, MA7, MA77, MA8, MA11, OIL7B, OIL9B, OIL11B, OIL30B, and OIL31B of Mitsubishi Chemical Corporation; PRINTEX-U, PRINTEXV, PRINTEX-140U, PRINTEX-140V, PRINTEX-95, PRINTEX-85, PRINTEX-75, PRINTEX-55, PRINTEX-45, PRINTEX300, PRINTEX-35, PRINTEX-25, PRINTEX-200, PRINTEX-40, PRINTEX-30, PRINTEX-3, PRINTEX-A, SPECIAL BLACK550, SPECIAL BLACK-350, SPECIAL BLACK-250, SPECIAL BLACK-100, and LAMP BLACK-101 of Evonik Industries (former Degussa AG); RAVEN-1100ULTRA, RAVEN-1080ULTRA, RAVEN-1060ULTRA, RAVEN-1040, RAVEN-1035, RAVEN-1020, RAVEN-1000, RAVEN-890H, RAVEN-890, RAVEN-880ULTRA, RAVEN-860ULTRA, RAVEN-850, RAVEN-820, RAVEN-790ULTRA, RAVEN780ULTRA, RAVEN-760ULTRA, RAVEN-520, RAVEN-500, RAVEN-460, RAVEN-450, RAVEN-430ULTRA, RAVEN-420, RAVEN-410, RAVEN-2500ULTRA, RAVEN-2000, RAVEN-1500, RAVEN-1255, RAVEN-1250, RAVEN-1200, RAVEN1190ULTRA and RAVEN-1170 of Columbia Carbon, and the like, but are not limited thereto.

According to another embodiment of the present disclosure, as the dispersant, any one or more selected from the group consisting of BYK LP N-22956, BYK LP N-22822, BYK LP N-23490, BYK LP N-22329, BYK LP N-23597, BYK LP N-23499, BYK LP N-22956, BYK LP N-22101, BYK LP N-23532, BYK LP N-23554, BYK LP N-22329, BYK LP N-23499 and the like may be additionally used or may replace.

According to another embodiment of the present disclosure, as the binder for dispersion, any one or more selected from the group consisting of BYK LP N-22956, BYK LP N-22822, BYK LP N-23490, BYK LP N-22329, BYK LP N-23597, BYK LP N-23499, BYK LP N-22956, BYK LP N-22101, BYK LP N-23532, BYK LP N-23554, BYK LP N-22329, BYK LP N-23499 and the like may be additionally used or may replace.

According to one embodiment of the present disclosure, the alkali-soluble polyimide resin including the repeating units represented by Chemical Formulae 1 to 3 may be included in 15 parts by weight to 65 parts by weight; or in 25 parts by weight to 60 parts by weight with respect to 100 parts by weight of a solid content of the photosensitive resin composition. As a preferred example, the alkali-soluble polyimide resin including the repeating units represented by Chemical Formulae 1 to 3 may be included in parts by weight to 55 parts by weight with respect to 100 parts by weight of a solid content of the photosensitive resin composition, however, the content is not limited thereto.

The alkali-soluble polyimide resin according to one embodiment of the present disclosure includes the repeating units represented by Chemical Formulae 1 to 3. The alkali-soluble polyimide resin may include a form in which Chemical Formulae 1 to 3 are repeated and bond in any order. In other words, the repeating units in the parentheses of m to p of Chemical Formulae 1 to 3 in the alkali-soluble polyimide resin according to one embodiment of the present disclosure may continuously bond, or may not continuously bond. For example, when m is 3, the alkali-soluble polyimide resin according to one embodiment of the present disclosure may include a form polymerized in a form of “-[Chemical Formula 1]-[Chemical Formula 1]-[Chemical Formula 1]-[Chemical Formula 2]n-[Chemical Formula 3]p-”, and may include a form polymerized in a form of “-[Chemical Formula 3]-[Chemical Formula 1]-[Chemical Formula 2]-[Chemical Formula 1]n-[Chemical Formula 1]p-”, however, the order is not limited to the orders described above, and the repeating units may be included in a form polymerized in any order and bonding in the polymer.

According to one embodiment of the present disclosure, X1 to X3 are the same as or different from each other, and each independently a tetravalent organic group.

According to one embodiment of the present disclosure, X1 to X3 are each independently a tetravalent organic group derived from an acid anhydride or a derivative thereof.

According to one embodiment of the present disclosure, X1 to X3 are each independently a tetravalent organic group derived from an acid dianhydride or a derivative thereof.

The tetravalent organic group of X1 to X3 of Chemical Formula 1 may be, for example, a tetravalent aromatic organic group, a tetravalent aliphatic organic group, or a tetravalent organic group in which an aromatic group and an aliphatic group are linked to each other, and at least one carbon may be replaced by C(═O), SO₂, NRx, S or O and Rx is an aryl group or an alkyl group.

According to one embodiment of the present disclosure, X1 to X3 are each independently a tetravalent organic group derived from tetracarboxylic anhydride or a derivative thereof.

According to one embodiment of the present disclosure, X1 to X3 are each independently a tetravalent organic group derived from tetracarboxylic dianhydride or a derivative thereof.

According to one embodiment of the present disclosure, X1 to X3 are each independently a tetravalent organic group derived from oxydiphthalic anhydride or a derivative thereof.

According to one embodiment of the present disclosure, X1 to X3 are each independently a tetravalent organic group derived from oxydiphthalic dianhydride or a derivative thereof.

According to one embodiment of the present disclosure, X1 to X3 are any one selected from among the following Chemical Formulae X-1 to X-5.

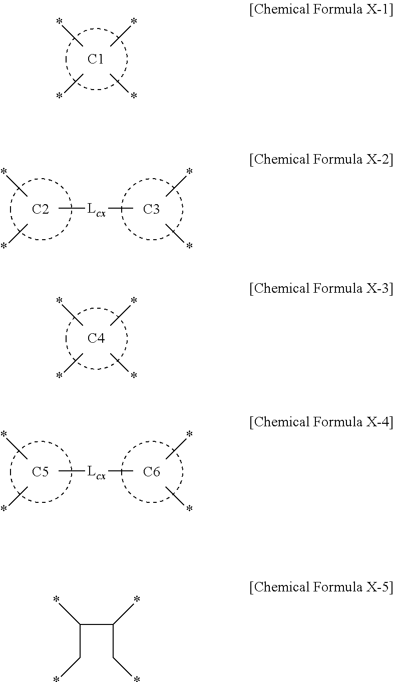

In Chemical Formulae X-1 to X-5,
the C1 ring to the C3 ring are the same as or different from each other, and each independently an aromatic hydrocarbon ring,
the C4 ring to the C6 ring are the same as or different from each other, and each independently an aliphatic hydrocarbon ring,
Lcx is any one selected from the group consisting of a single bond, —O—, —CO—, —COO—, —S—, —SO—, —SO₂—, —CRC1RC2-, —(CH₂)_{CZ}—, —O(CH₂)_{CZ}O—, —COO(CH₂)_{CZ}OCO—, —O(C₆H₆)_{CZ}O_{CZ}—, —CONH— or a phenylene group,
RC1 and RC2 are the same as or different from each other, and each independently an alkyl group having 1 to 10 carbon atoms or a haloalkyl group having 1 to 10 carbon atoms, and
cz is an integer of 1 to 10.

According to one embodiment of the present disclosure, the C1 ring to the C6 ring may be substituted with a halogen group or an alkyl group having 1 to 10 carbon atoms.

According to one embodiment of the present disclosure, the C1 ring to the C3 ring are the same as or different from each other, and each independently an aromatic hydrocarbon ring having 6 to 18 carbon atoms.

According to one embodiment of the present disclosure, the C4 ring to the C6 ring are the same as or different from each other, and each independently an aliphatic hydrocarbon ring having 4 to 18 carbon atoms.

According to one embodiment of the present disclosure, Chemical Formula X-1 is any one selected from among the following structures.

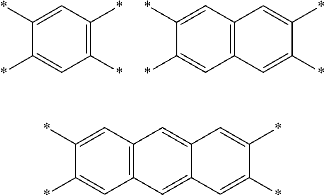

In the structures, * means a linking site.

According to one embodiment of the present disclosure, Chemical Formula X-2 is any one selected from among the following structures.

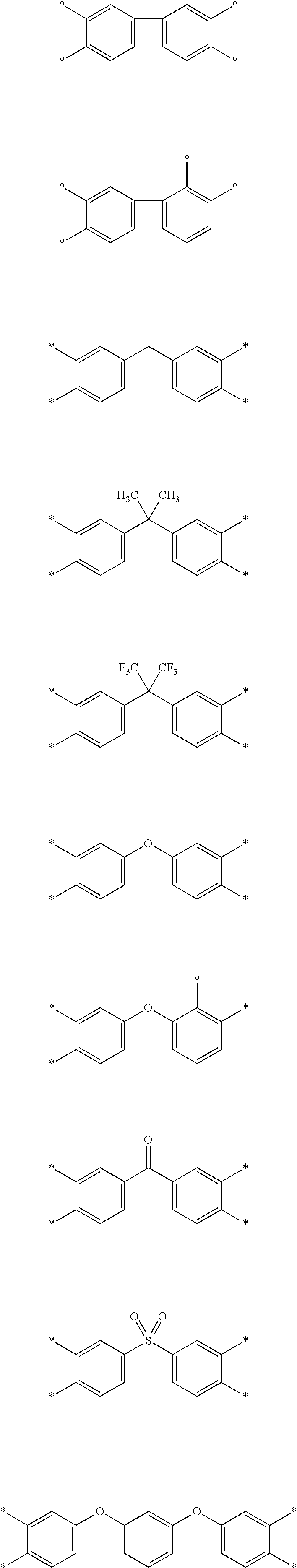

In the structures, * means a linking site.

According to one embodiment of the present disclosure Chemical Formula X-3 is any one selected from among the following structures.

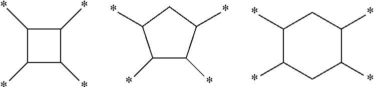

In the structures, * means a linking site.

According to one embodiment of the present disclosure, Chemical Formula X-4 is the following structure.

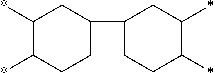 [SMILES: *C1CCC(C2CCC(*)C(*)C2)CC1*]

In the structure, * means a linking site.

According to one embodiment of the present disclosure, X1 to X3 are any one selected from among the following structures.

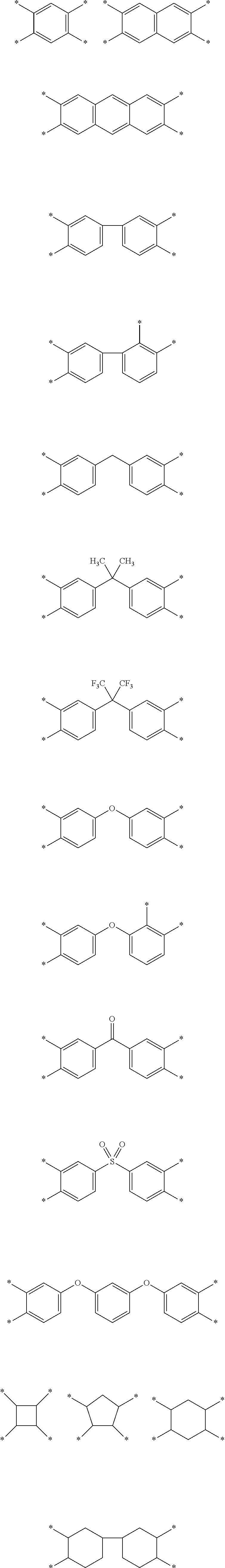

According to preferred one embodiment of the present disclosure, X1 to X3 are any one selected from among the following structures.

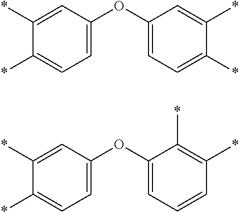

According to one embodiment of the present disclosure, Y1 to Y3 are the same as or different from each other, and each independently a divalent organic group.

According to one embodiment of the present disclosure, Y1 to Y3 are the same as or different from each other, and each independently an organic group derived from diamine or a derivative thereof.

According to one embodiment of the present disclosure, Y1 to Y3 are the same as or different from each other, and each independently a divalent organic group derived from diamine or a derivative thereof.

According to one embodiment of the present disclosure, Y1 to Y3 are the same as or different from each other, and each independently a divalent organic group including a hydroxyl group; a phenolic hydroxyl group; or a substituted or unsubstituted haloalkyl group.

According to one embodiment of the present disclosure, Y1 to Y3 are the same as or different from each other, and each independently a divalent organic group including a hydroxyl group; a phenolic hydroxyl group; or a substituted or unsubstituted haloalkyl group having 1 to 10 carbon atoms.

According to one embodiment of the present disclosure, Y1 to Y3 are the same as or different from each other, and each independently a divalent organic group including a hydroxyl group; a phenolic hydroxyl group; or a haloalkyl group.

According to one embodiment of the present disclosure, Y1 to Y3 are the same as or different from each other, and each independently a divalent organic group including a hydroxyl group; a phenolic hydroxyl group; or a haloalkyl group having 1 to 10 carbon atoms.

According to one embodiment of the present disclosure, Y1 to Y3 are the same as or different from each other, and each independently a divalent organic group including a hydroxyl group, a phenolic hydroxyl group or a trifluoromethyl group.

According to one embodiment of the present disclosure, Y1 to Y3 are the same as or different from each other, and each independently a divalent organic group including a hydroxyl group; a phenolic hydroxyl group; or a trifluoromethyl group, and derived from diamine or a derivative thereof.

The divalent organic group may be a divalent aliphatic organic group, a divalent aromatic organic group, or a divalent organic group in which an aliphatic group and an aromatic group are linked to each other, and at least one carbon may be replaced by C(═O), SO₂, NRx, S or O, and Rx is an aryl group or an alkyl group and may be substituted with a halogen group, a hydroxyl group, a carboxyl group, a thiol group, a sulfonic acid group or an alkyl group.

According to one embodiment of the present disclosure, Y1 to Y3 are any one selected from among the following Chemical Formulae Y-1 to Y-4.

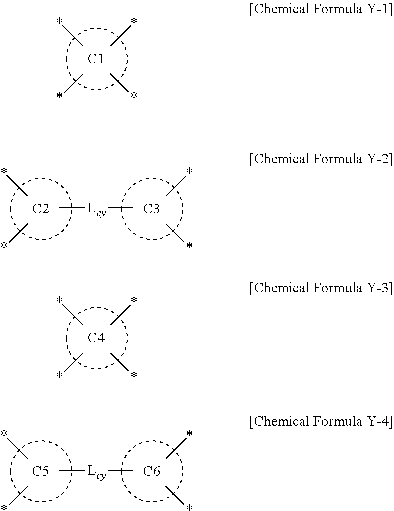

In Chemical Formulae Y-1 to Y-4,
Lcy is any one selected from the group consisting of a single bond, —O—, —CO—, —COO—, —S—, —SO—, —SO₂—, —CRC1RC2-, —C(C₆H₆)—, —C(C₆H₆)— and —NRC3-,
RC3 is an aryl group, and
the C1 ring to the C6 ring, RC1 and RC2 have the same definitions as in Chemical Formulae X-1 to X-5.

According to one embodiment of the present disclosure, RC3 is a phenyl group.

According to one embodiment of the present disclosure, the C1 ring to the C6 ring and Lcy may be each independently substituted with a substituent including a hydroxyl group.

According to one embodiment of the present disclosure, the C1 ring to the C6 ring and Lcy may be each independently substituted with a hydroxyl group or a carboxyl group.

According to one embodiment of the present disclosure, Chemical Formula Y-1 is any one selected from among the following structures.

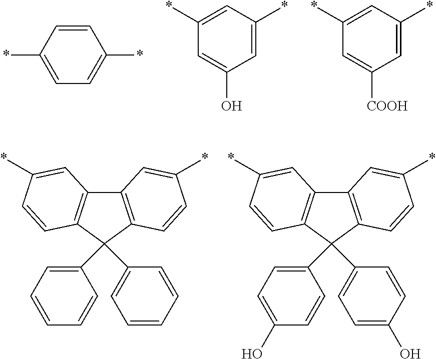

In the structures, * means a linking site.

According to one embodiment of the present disclosure, Chemical Formula Y-2 is any one selected from among the following structures.

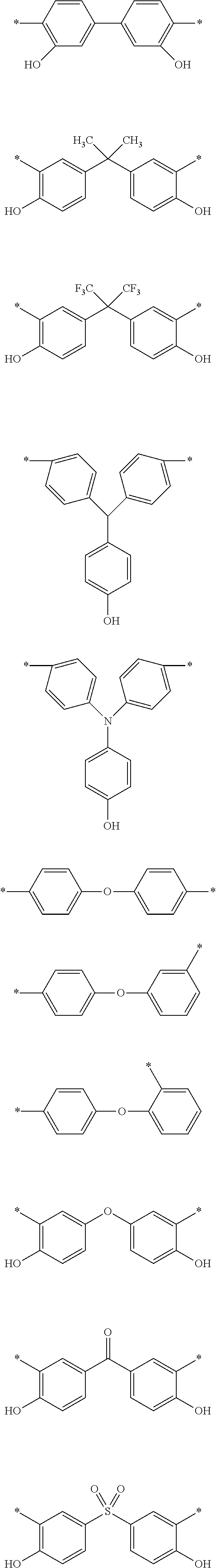

In the structures, * means a linking site.

According to one embodiment of the present disclosure, Chemical Formula Y-3 is the following structure.

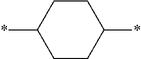 [SMILES: *C1CCC(*)CC1]

In the structure, * means a linking site.

According to one embodiment of the present disclosure, Y1 to Y3 are any one selected from among the following structural formulae.

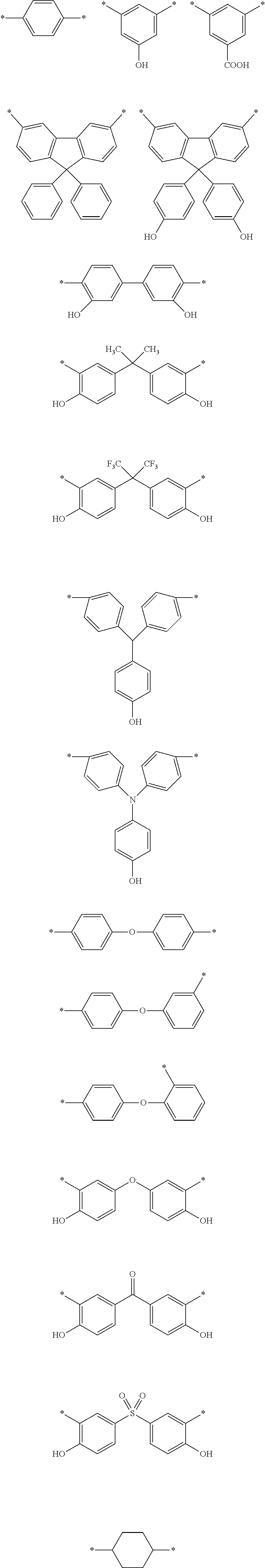

According to one embodiment of the present disclosure, R7 is hydrogen; deuterium; a hydroxyl group; a halogen group; a nitro group; a nitrile group; a substituted or unsubstituted alkyl group; a substituted or unsubstituted alkenyl group; a substituted or unsubstituted alkynyl group; a substituted or unsubstituted alkoxy group; a substituted or unsubstituted aryloxy group; a substituted or unsubstituted cycloalkyl group; a substituted or unsubstituted aryl group; a substituted or unsubstituted heterocyclic group; or a photopolymerizable unsaturated group.

The photosensitive resin composition according to one embodiment of the present disclosure may increase adhesion for a substrate used in a display apparatus such as an organic light emitting diode through bonding strength obtained from the photopolymerizable unsaturated group.

According to one embodiment of the present disclosure, R7 is hydrogen; deuterium; a hydroxyl group; a halogen group; a nitro group; a nitrile group; a substituted or unsubstituted alkyl group having 1 to carbon atoms; a substituted or unsubstituted alkenyl group having 1 to 30 carbon atoms; a substituted or unsubstituted alkynyl group having 1 to 30 carbon atoms; a substituted or unsubstituted alkoxy group having 1 to 30 carbon atoms; a substituted or unsubstituted aryloxy group having 6 to 30 carbon atoms; a substituted or unsubstituted cycloalkyl group having 3 to 30 carbon atoms; a substituted or unsubstituted aryl group having 6 to 30 carbon atoms; a substituted or unsubstituted heterocyclic group having 2 to 30 carbon atoms; or a photopolymerizable unsaturated group.

According to one embodiment of the present disclosure, R7 is hydrogen; deuterium; a hydroxyl group; a halogen group; a substituted or unsubstituted alkenyl group; a substituted or unsubstituted alkynyl group; a substituted or unsubstituted alkoxy group; a substituted or unsubstituted aryloxy group; or a photopolymerizable unsaturated group.

According to one embodiment of the present disclosure, R7 is hydrogen; deuterium; a hydroxyl group; a halogen group; a substituted or unsubstituted alkenyl group having 1 to 30 carbon atoms; a substituted or unsubstituted alkynyl group having 1 to 30 carbon atoms; a substituted or unsubstituted alkoxy group having 1 to 30 carbon atoms; a substituted or unsubstituted aryloxy group having 6 to 30 carbon atoms; or a photopolymerizable unsaturated group.

According to one embodiment of the present disclosure, R7 is a photopolymerizable unsaturated group.

According to one embodiment of the present disclosure, the photopolymerizable unsaturated group may be a substituted or unsubstituted acryloyl group; a substituted or unsubstituted acrylate group or the like. Specifically, the (meth)acrylate group may be one type selected from the group consisting of propyl acrylate, propylene glycol methacrylate, dipentaerythritol hexaacrylate, dipentaerythritol acrylate, neopentyl glycol diacrylate, 6-hexanediol diacrylate, 1,6-hexanediol acrylate tetraethylene glycol methacrylate, bisphenoxyethyl alcohol diacrylate, trishydroxyethyl isocyanurate trimethacrylate, trimethylpropane trimethacrylate, diphenylpentaerythritol hexaacrylate, pentaerythritol trimethacrylate, pentaerythritol tetramethacrylate and dipentaerythritol hexamethacrylate, or a mixture of two or more types thereof, but is not limited thereto.

According to one embodiment of the present disclosure, R7 is a substituted or unsubstituted acryloyl group; or a substituted or unsubstituted acrylate group.

According to one embodiment of the present disclosure, R7 is a substituted or unsubstituted propyl acrylate.

According to one embodiment of the present disclosure, R7 is represented by the following Chemical Formula B.

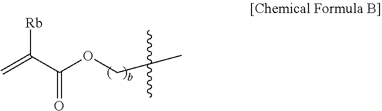

Rb is hydrogen; or an alkyl group having 1 to 4 carbon atoms,
b is an integer of 1 to 10, and
in Chemical Formula B,

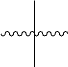

means a site bonding to N of Chemical Formula A.

According to preferred one embodiment of the present disclosure, Rb of Chemical Formula B is hydrogen.

According to one embodiment of the present disclosure, b is an integer of 1. According to another embodiment of the present disclosure, b is an integer of 2. According to still another embodiment of the present disclosure, b is an integer of 3. According to still another embodiment of the present disclosure, b is an integer of 4. According to still another embodiment of the present disclosure, b is an integer of 5. According to still another embodiment of the present disclosure, b is an integer of 6. According to still another embodiment of the present disclosure, b is an integer of 7. According to still another embodiment of the present disclosure, b is an integer of 8. According to still another embodiment of the present disclosure, b is an integer of 9. According to still another embodiment of the present disclosure, b is an integer of 10.

According to one embodiment of the present disclosure, p/(m+n+p) may be from 0.03 to 0.15 for m to p of Chemical Formulae 1 to 3. According to another embodiment, p/(m+n+p) may be from 0.08 to 0.15 or less for m to p of Chemical Formulae 1 to 3. According to still another embodiment, p/(m+n+p) may be from 0.1 to 0.15 or less for m to p of Chemical Formulae 1 to 3.

As for m to p of Chemical Formulae 1 to 3, each ratio of m, n and p with respect to the sum of m+n+p means a ratio of ring-closure or no ring-closure. Specifically, the structure in the parenthesis for m or n is imidized and is a closed ring. Accordingly, the sum of the ratio of m and the ratio of n with respect to the total sum of m+n+p means a ring-closure rate of the alkali-soluble polyimide resin. On the other hand, the structure in the parenthesis for p is not imidized and therefore, is not a closed ring. Accordingly, the ratio of p with respect to the sum of m+n+p means a ratio of no ring-closure in the alkali-soluble polyimide resin.

The photosensitive resin composition according to one embodiment of the present disclosure may have a ring-closure rate of 85% to 97%. According to another embodiment, the photosensitive resin composition may have a ring-closure rate of 85% to 95%. According to still another embodiment, the photosensitive resin composition may have a ring-closure rate of 85% to 90%. According to still another embodiment, the photosensitive resin composition may have a ring-closure rate of 90% to 95%. However, the range of the ring-closure rate of the photosensitive resin composition is not limited to the specific numerical ranges described above.

As above, the photosensitive resin composition including the alkali-soluble polyimide resin having a ring-closure rate of 85% to 95% according to one embodiment of the present disclosure prevents swelling or a decrease in solubility caused by the ring closure of the side chain during development. Specifically, it prevents a decrease in solubility or swelling caused by an increase in the ring-closure rate due to imidization during the process such as development.

According to one embodiment of the present disclosure, the alkali-soluble polyimide resin of the photosensitive resin composition has a weight average molecular weight of 1,000 g/mol to 35,000 g/mol; 2,000 g/mol to 33,000 g/mol; or 2,500 g/mol to 33,000 g/mol. When the weight average molecular weight is in the above-mentioned range, the photosensitive resin composition including the alkali-soluble polyimide resin has excellent physical and chemical properties, has proper viscosity, and has superior adhesion with a substrate.

According to one embodiment of the present disclosure, the coloring agent may be used as a dispersion liquid together with the pigment, the dispersant and the binder for dispersion. As a solvent for preparing the dispersion liquid, descriptions on a solvent for preparing the photosensitive resin composition according to one embodiment of the present disclosure to describe below may be applied in the same manner.

According to one embodiment of the present disclosure, as the solvent, compounds known to allow formation of a photosensitive resin composition in the art may be used without particular limit. For example, the solvent may be one or more types of compounds selected from the group consisting of esters, ethers, ketones, aromatic hydrocarbons and sulfoxides.

The ester-based solvent may be ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, gamma-butyrolactone, epsilon-caprolactone, delta-valerolactone, alkyl oxyacetate (example: methyl oxyacetate, ethyl oxyacetate, butyl oxyacetate (for example, methyl methoxyacetate, ethyl methoxyacetate, butyl methoxyacetate, methyl ethoxyacetate, ethyl methoxyacetate or the like)), alkyl 3-oxypropionates (example: methyl 3-oxypropionate, ethyl 3-oxypropionate or the like (for example, methyl 3-methoxypropionate, ethyl 3-methoxypropionate, methyl 3-ethoxypropionate, ethyl 3-ethoxypropionate or the like)), alkyl 2-oxypropionates (example: methyl 2-oxypropionate, ethyl 2-oxypropionate, propyl 2-oxypropionate or the like (for example, methyl 2-methoxypropionate, ethyl 2-methoxypropionate, propyl 2-methoxypropionate, methyl 2-ethoxypropionate, ethyl 2-ethoxypropionate)), methyl 2-oxy-2-methylpropionate and ethyl 2-oxy-2-methylpropionate (for example, methyl 2-methoxy-2-methylpropionate, ethyl 2-ethoxy-2-methylpropionate or the like), methyl pyruvate, ethyl pyruvate, propyl pyruvate, methyl acetoacetate, ethyl acetoacetate, methyl 2-oxobutanoate, 2-ethyl 2-oxobutanoate or the like.

The ether-based solvent may be diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate or the like.

The ketone-based solvent may be methyl ethyl ketone, cyclohexanone, cyclopentanone, 2-heptanone, 3-heptanone, N-methyl-2-pyrrolidone or the like.

The aromatic hydrocarbon-based solvent may be toluene, xylene, anisole, limonene or the like.

The sulfoxide-based solvent may be dimethyl sulfoxide or the like.

In one embodiment of the present disclosure, the solvent may be propylene glycol monomethyl ether acetate.

In one embodiment of the present disclosure, the solvent may preferably be a mixture solution of propylene glycol monomethyl ether acetate, diethylene glycol methyl ethyl ether and gamma butyrolactone.

In the solvent, propylene glycol monomethyl ether acetate, diethylene glycol methyl ethyl ether and gamma butyrolactone may be mixed in a weight ratio of 50:20:2 to 70:50:10. In the solvent, propylene glycol monomethyl ether acetate, diethylene glycol methyl ethyl ether and gamma butyrolactone may be preferably mixed in a weight ratio of 60:35:5.

According to one embodiment of the present disclosure, the solvent may be included in 10 parts by weight to 85 parts by weight; or in 15 parts by weight to 80 parts by weight with respect to 100 parts by weight of the photosensitive resin composition.

When the solvent is included in the above-mentioned range or, when the mixture solution is used as the solvent, the mixing ratio is in the above-mentioned range, coatability of the photosensitive resin composition is excellent, or a film having excellent flatness may be obtained.

According to one embodiment of the present disclosure, the photosensitive resin composition may further include additives required by those skilled in the art.

As the additive, a multifunctional monomer, a crosslinking agent, a photopolymerization initiator, a surfactant, a silane coupling agent and the like may be included, however, the additive is not limited thereto.

According to one embodiment of the present disclosure, the photosensitive resin composition further includes at least one of a multifunctional monomer, a crosslinking agent, a photopolymerization initiator, a surfactant and a silane coupling agent.

According to one embodiment of the present disclosure, the photosensitive resin composition further includes a multifunctional monomer, a crosslinking agent, a photopolymerization initiator, a surfactant and a silane coupling agent.

According to one embodiment of the present disclosure, the multifunctional monomer may be any one or more of unsaturated carboxylic acid esters; aromatic vinyls; unsaturated ethers; unsaturated imides; and acid anhydrides, and other multifunctional monomers known in the art may be further included.

The multifunctional monomer may be included in 1 parts by weight to 40 parts by weight; or in 15 parts by weight to 35 parts by weight with respect to 100 parts by weight of a solid content of the photosensitive resin composition. As a preferred example, the multifunctional monomer may be included in 20 parts by weight to 30 parts by weight with respect to 100 parts by weight of a solid content of the photosensitive resin composition, however, the content is not limited thereto.

As a specific example, the unsaturated carboxylic acid ester may be selected from the group consisting of benzyl (meth)acrylate, methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, isobornyl (meth)acrylate, ethylhexyl (meth)acrylate, 2-phenoxyethyl (meth)acrylate, tetrahydrofurfuryl (meth)acrylate, hydroxyethyl (meth)acrylate, 2-hydroxypropyl (meth)acrylate, 2-hydroxy-3-chloropropyl (meth)acrylate, 4-hydroxybutyl (meth)acrylate, acyloctyloxy-2-hydroxypropyl (meth)acrylate, glycerol (meth)acrylate, 2-methoxyethyl (meth)acrylate, 3-methoxybutyl (meth)acrylate, ethoxydiethylene glycol (meth)acrylate, methoxytriethylene glycol (meth)acrylate, methoxytripropylene glycol (meth)acrylate, poly(ethylene glycol) methyl ether (meth)acrylate, phenoxydiethylene glycol (meth)acrylate, p-nonylphenoxypolyethylene glycol (meth)acrylate, p-nonylphenoxypolypropylene glycol (meth)acrylate, glycidyl (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, methyl α-hydroxymethyl acrylate, ethyl α-hydroxymethyl acrylate, propyl α-hydroxymethyl acrylate and butyl α-hydroxymethyl acrylate, but is not limited thereto.

As another example of the multifunctional monomer, one or more types of pentaerythritol tetra(meth)acrylate, pentaerythritol tri(meth)acrylate, dipentaerythritol penta(meth)acrylate, dipentaerythritol hexa(meth)acrylate and the like may be used, however, the multifunctional monomer is not limited thereto.

According to one embodiment of the present disclosure, a content of the alkali-soluble hydroxyl group is 30 parts by weight or greater with respect to 100 parts by weight of the multifunctional monomer.

According to one embodiment of the present disclosure, a content of the alkali-soluble hydroxyl group is from 30 parts by weight to 85 parts by weight with respect to 100 parts by weight of the multifunctional monomer. As above, the alkali-soluble polyimide resin including 30 parts by weight or more of the alkali-soluble hydroxyl group based on 100 parts by weight of the multifunctional monomer may have excellent developability. The content of the alkali-soluble hydroxyl group may be derived from a ratio of the parts by weight of the hydroxyl group with respect to 100 parts by weight of the compound including the alkali-soluble hydroxyl group. For example, in a single phenol molecule, a content of one hydroxyl group present in the single phenol molecule may be obtained through a ratio of the parts by weight of the one hydroxyl group present in the single phenol molecule with respect to 100 parts by weight of the phenol. Specifically, phenol has a molecular weight of 94 g/mol and one hydroxyl group present in the phenol has a molecular weight of 17 g/mol, and therefore, the hydroxyl group is included in a ratio of approximately 18.09 parts by weight with respect to 100 parts by weight of the phenol.

According to one embodiment of the present disclosure, a content of the alkali-soluble hydroxyl group is 50 parts by weight or greater with respect to 100 parts by weight of the multifunctional monomer.

According to one embodiment of the present disclosure, a content of the alkali-soluble hydroxyl group is from 50 parts by weight to 70 parts by weight with respect to 100 parts by weight of the multifunctional monomer.

According to one embodiment of the present disclosure, when the content of the alkali-soluble hydroxyl group is from 50 parts by weight to 70 parts by weight with respect to 100 parts by weight of the multifunctional monomer, the alkali-soluble polyimide resin may have excellent developability even in the weight average molecular weight range of 1,000 g/mol to 20,000 g/mol.

According to another embodiment of the present disclosure, a content of the alkali-soluble hydroxyl group is 70 parts by weight or greater with respect to 100 parts by weight of the multifunctional monomer.

According to another embodiment of the present disclosure, a content of the alkali-soluble hydroxyl group is from 70 parts by weight to 85 parts by weight with respect to 100 parts by weight of the multifunctional monomer.

According to another embodiment of the present disclosure, when the content of the alkali-soluble hydroxyl group is from 70 parts by weight to 85 parts by weight with respect to 100 parts by weight of the multifunctional monomer, the alkali-soluble polyimide resin may have excellent developability even in the weight average molecular weight range of 20,000 g/mol or greater.

When the weight average molecular weight of the alkali-soluble polyimide resin satisfies the above-described range and the content of the alkali-soluble hydroxyl group satisfies the above-mentioned range based on 100 parts by weight of the multifunctional monomer, an effect of increasing developability for a developing solution or enhancing sensitivity or increasing mechanical properties may be obtained.

The crosslinking agent induces a crosslinking reaction between the alkali-soluble polyimide resin or other additive components to increase heat resistance and chemical resistance of a produced film. Herein, compounds including a functional group such as an acrylic group or an isocyanate group may be used as the crosslinking agent. In addition, the crosslinking agent may be, for example, a thermal crosslinking agent, and as such a thermal crosslinking agent, compounds including a thermally reactive functional group such as a methylol group or an epoxy group may be used. As a specific example, crosslinking agents generally used in the art such as DML-PC, DML-PEP, DML-OC, DML-OEP, DML-34X, DML-PTBP, DML-PCHP, DML-OCHP, DML-PFP, DML-PSBP, DML-POP, DML-MBOC, DML-MBPC, DML-MTrisPC, DML-BisOC-Z, DML-BisOCHP-Z, DML-BPC, DML-BisOC-P, DMOM-PC, DMOM-PTBP, DMOM-MBPC, TriML-P, TriML-35XL, TML-HQ, TML-BP, TML-pp-BPF, TML-BPE, TML-BPA, TML-BPAF, TML-BPAP, TMOM-BP, TMOM-BPE, TMOM-BPA, TMOM-BPAF, TMOM-BPAP, HML-TPPHBA, HML-TPHAP, HMOM-TPPHBA, HMOM-TPHAP (hereinbefore, trade names, manufactured by Honshu Chemical Industry Co., Ltd.), “NIKALAC” (registered trademark) MX-290, “NIKALAC” (registered trademark) MX-280, “NIKALAC” (registered trademark) MX-270, “NIKALAC” (registered trademark) MX-279, “NIKALAC” (registered trademark) MW-100LM and “NIKALAC” (registered trademark) MX-750LM (hereinbefore, trade names, manufactured by Sanwa Chemical Co., Ltd.) may be used.

According to one embodiment of the present disclosure, the crosslinking agent may be included in 0.1 parts by weight to 40 parts by weight with respect to 100 parts by weight of a solid content of the photosensitive resin composition. As a preferred example, the crosslinking agent may be included in 20 parts by weight to 25 parts by weight with respect to 100 parts by weight of a solid content of the photosensitive resin composition, however, the content is not limited thereto.

The photopolymerization initiator is a material that triggers crosslinking through generating radicals by light, and one or more types of compounds selected from the group consisting of acetophenone-based compounds, biimidazole-based compounds, triazine-based compounds and oxime-based compounds are preferably mixed and used.

According to one embodiment of the present disclosure, the photopolymerization initiator may be included in 0.1 parts by weight to 10 parts by weight with respect to 100 parts by weight of a solid content of the photosensitive resin composition. As a preferred example, the crosslinking agent may be included in 4 parts by weight to 5 parts by weight with respect to 100 parts by weight of a solid content of the photosensitive resin composition, however, the content is not limited thereto.

The surfactant is a silicone-based surfactant or a fluorine-based surfactant. Specifically, as the silicone-based surfactant, BYK-077, BYK-085, BYK-300, BYK-301, BYK-302, BYK-306, BYK-307, BYK-310, BYK-320, BYK-322, BYK-323, BYK-325, BYK-330, BYK-331, BYK-333, BYK-335, BYK-341v344, BYK-345v346, BYK-348, BYK-354, BYK-355, BYK-356, BYK-358, BYK-361, BYK-370, BYK-371, BYK-375, BYK-380, BYK-390 and the like of BYK-Chemie GmbH may be used, and as the fluorine-based surfactant, F-114, F-177, F-410, F-411, F-450, F-493, F-494, F-443, F-444, F-445, F-446, F-470, F-471, F-472SF, F-474, F-475, F-477, F-478, F-479, F-480SF, F-482, F-483, F-484, F-486, F-487, F-172D, MCF-350SF, TF-1025SF, TF-1117SF, TF-1026SF, TF-1128, TF-1127, TF-1129, TF-1126, TF-1130, TF-1116SF, TF-1131, TF1132, TF1027SF, TF-1441, TF-1442 and the like of DIC (DaiNippon Ink & Chemicals) may be used, however, the silicone-based surfactant and the fluorine-based surfactant are not limited thereto.

According to one embodiment of the present disclosure, the surfactant may be included in 0.1 parts by weight to 5 parts by weight with respect to 100 parts by weight of a solid content of the photosensitive resin composition. As another example, the surfactant may be included in 0.2 parts by weight to 0.4 parts by weight with respect to 100 parts by weight of a solid content of the photosensitive resin composition. As a preferred example, the surfactant may be included in 0.25 parts by weight to 0.35 parts by weight with respect to 100 parts by weight of a solid content of the photosensitive resin composition, however, the content is not limited thereto.

The silane coupling agent may be used for, for example, improving dispersability of a thermally conductive filler such as alumina, and as long as having functions as above, various types thereof known in the art may be used without limit. The silane coupling agent means a compound including a hydrolysable silyl group or silanol group. In addition, the silane coupling agent may increase mutual adhesion between a film produced through curing and a specific one surface of a substrate, and may thereby increase heat resistance and chemical resistance. As an example of the silane coupling agent, one or more types selected from among octyltrimethoxysilane, dodecyltrimethoxysilane, octadecyltrimethoxysilane and the like may be used, however, the silane coupling agent is not limited thereto.

According to one embodiment of the present disclosure, the silane coupling agent may be included in 0.1 parts by weight to 2 parts by weight with respect to 100 parts by weight of a solid content of the photosensitive resin composition. As a preferred example, the silane coupling agent may be included in 0.2 parts by weight to 1 parts by weight with respect to 100 parts by weight of a solid content of the photosensitive resin composition, however, the content is not limited thereto.

According to one embodiment of the present disclosure, the photosensitive resin composition may further include additional additives. As the additional additive, an antioxidant, a thermal polymerization inhibitor and the like may be included, however, the additional additive is not limited thereto.

The antioxidant may perform a role or preventing a chain reaction that generates radicals during the polymer film formation. Herein, as the antioxidant, phenol-based antioxidants and the like may be included and 2,2-thiobis(4-methyl-6-t-butylphenol), 2,6-g,t-butylphenol or the like, which is an antioxidant generally used in the art, may be used, and as the ultraviolet absorber, 2-(3-t-butyl-5-methyl-2-hydroxyphenyl)-5-chloro-benzotriazole, alkoxybenzophenone or the like may be used, however, the antioxidant and the ultraviolet absorber are not limited thereto.

According to one embodiment of the present disclosure, when the antioxidant is included, the antioxidant may be included in 0.1 parts by weight to 10 parts by weight; or in 0.2 parts by weight to 1 parts by weight with respect to 100 parts by weight of a solid content of the photosensitive resin composition.

As the thermal polymerization inhibitor, hydroquinone, p-methoxyphenol, di-t-butyl-p-cresol, pyrogallol, t-butylcatechol, benzoquinone, 4,4-thiobis(3-methyl-6-t-butylphenol), 2,2-methylenebis(4-methyl-6-t-butylphenol), 2-mercaptoimidazole or the like may be used.

According to one embodiment of the present disclosure, when the thermal polymerization inhibitor is included, the thermal polymerization inhibitor may be included in 0.1 parts by weight to 10 parts by weight; or in 0.2 parts by weight to 1 parts by weight with respect to 100 parts by weight of a solid content of the photosensitive resin composition.

One embodiment of the present disclosure provides a photosensitive material including the photosensitive resin composition.

One embodiment of the present disclosure provides a photosensitive material prepared using the photosensitive resin composition. More specifically, the photosensitive resin composition of the present disclosure is coated on a base using a proper method to form a photosensitive material having a thin film or pattern form.

The coating method is not particularly limited, however, a spray method, a roll coating method, a spin coating method and the like may be used, and a spin coating method is generally used widely. In addition, after forming the coating film, the residual solvent may be partially removed under vacuum in some cases.

The photopolymerizable unsaturated group included in the photosensitive resin composition or the photosensitive material according to one embodiment of the present disclosure may be cured by a light source such as mercury vapor arc, carbon arc or Xe art emitting light having a wavelength of 250 nm to 450 nm, however, the method is not limited thereto.

The photosensitive resin composition according to one embodiment of the present disclosure may be used in a pigment-dispersed photosensitive material for manufacturing a thin film transistor liquid crystal display (TFT LCD) color filter, a photosensitive material for a black matrix of a thin film transistor liquid crystal display (TFT LCD) or an organic light emitting diode, a photosensitive material for forming an overcoat, a column spacer photosensitive material, a photocurable paint, a photocurable ink, a photocurable adhesive, a printing plate, a photosensitive material for a printed circuit board, a photosensitive material for a plasma display panel (PDP), and the like, and the application is not particularly limited.

One embodiment of the present disclosure provides a photosensitive resin composition for a color filter or a photosensitive material for a color filter.

According to one embodiment of the present disclosure, the color filter may be manufactured using the photosensitive resin composition described above or the photosensitive material described above. The photosensitive resin composition may be coated on a substrate to form a coating film, and the coating film may be exposed, developed and cured to form a color filter.

According to one embodiment of the present disclosure, the substrate may be a glass plate, a silicon wafer, a plate of a plastic base such as polyethersulfone (PES) or polycarbonate (PC), or the like, and the type is not particularly limited.

According to one embodiment of the present disclosure, the color filter may include a red pattern, a green pattern, a blue pattern or a black matrix.

According to another embodiment, the color filter may further include an overcoat layer.

With the purpose of enhancing contrast, a grid black pattern referred to as a black matrix may be disposed between color pixels of the color filter. Chromium may be used as a material of the black matrix. In this case, a method of depositing chromium on the entire glass substrate and forming a pattern by etching treatment may be used. However, considering high costs of the process, high reflectivity of the chromium, and environmental pollution caused by the chromium waste solution, a resin black matrix using a pigment dispersion method capable of micro-processing may be used.

The black matrix according to one embodiment of the present disclosure may further include a black pigment or black dye as an additional colorant in addition to the colorant included in the coloring agent described above. For example, carbon black may be used either alone, or carbon black and a coloring pigment may be mixed and used, and, since a coloring pigment lacking a light-shielding property is mixed, there is an advantage in that film strength or adhesion for a substrate does not decline even when the amount of the colorant relatively increases.

The black matrix according to one embodiment of the present disclosure may include a black pigment or black dye as an additional colorant instead of the colorant included in the coloring agent described above.

A preferred one embodiment of the present disclosure provides a photosensitive resin composition for a black matrix or a photosensitive material for a black matrix.

The for a black matrix includes all meanings such as an application for forming a black matrix, an application included in a black matrix, and the like.

One embodiment of the present disclosure provides a black matrix including the photosensitive resin composition described above.

One embodiment of the present disclosure provides a display apparatus including the color filter.

The display apparatus may be any one of a plasma display panel (PDP), a light emitting diode (LED), an organic light emitting diode (OLED), a liquid crystal display (LCD), a thin film transistor-liquid crystal display (LCD-TFT) and a cathode ray tube (CRT).

One embodiment of the present disclosure provides an electronic device including the black matrix described above.

The electronic device may include all of an interlayer insulating film of a semiconductor device, the color filter described above, the black matrix described above, an overcoat, a column spacer, a passivation film, a buffer coat film, an insulating film for a multilayer print substrate, a cover coat of a flexible copper clad plate, a buffer coat film, an insulating film solder resist film for a multilayer print substrate, an insulating film of an OLED, a protective film of a thin film transistor of a liquid crystal display device, an electrode protective film of an organic EL device and a semiconductor protective film, an OLED insulating film, an LCD insulating film, a semiconductor insulating film, the display apparatus described above and the like, but is not limited thereto.

Hereinafter, the present disclosure will be described in detail with reference to examples in order to specifically describe the present disclosure. However, the examples according to the present disclosure may be modified to various different forms, and the scope of the present disclosure is not to be construed as being limited to the examples described below. Examples of the present disclosure are provided in order to more fully describe the present disclosure to those having average knowledge in the art.

### Preparation Example

<Preparation Example of Resin A>

In a round bottom flask, 2,2-bis(3-amino-4-hydroxyphenyl)hexafluoropropane (Bis-AP-AF) (14.4 g, 0.31 mol) was introduced to propylene glycol monomethyl ether acetate (PGMEA) (500 g) and dissolved therein at 60° C. Bis(3,4-dicarboxyphenyl)ether dianhydride (ODPA) (91.1 g, 0.29 mol) was added thereto, and after stirring the result for 2 hours, phthalic anhydride (7.2 g, 0.03 mol) was added thereto as an end sealant, and the result was further stirred for 2 hours. Then, the temperature was raised to 170° C., and the result was further stirred for 6 hours. After that, the temperature was lowered to room temperature. A weight average molecular weight (Mw) of the polymerized Resin A measured through gel permeation chromatography (GPC) was 15,000 g/mol, and as a result of infrared spectrometer (IR) measurement on Resin A, a degree of imidization (DOI) was 92%. The weight average molecular weight of the polymerized Resin A was measured by gel permeation chromatography under a tetrahydrofuran (THF) solvent.

<Preparation Example of Resins A1 and A2>

The polymerized Resin A solution was stirred at room temperature. Acryloyloxyethyl isocyanate (2-isocyanatoethyl acrylate, AOL, CAS 13641-96-8) was added in 20 mol % and 60 mol % based on a total equivalent of 100 mol % of 2,2-bis(3-amino-4-hydroxyphenyl)hexafluoropropane (Bis-AP-AF) of Resin A. The reactor temperature was raised to 60° C., and the result was stirred for 12 hours to respectively polymerize Resins A1 and A2. Weight average molecular weights (Mw) of the polymerized Resins A1 and A2 measured through gel permeation chromatography (GPC) were 9,730 g/mol and 9,840 g/mol, and as a result of infrared spectrometer (IR) measurements on Resins A1 and A2, degrees of imidization (DOI) were 93.90% and 93.80%.

<Preparation of Resins B and C>

Resins B and C were prepared in the same manner as in Preparation Example of Resin A except that the reaction materials were prepared as in the following Table 1.

TABLE 1

| | Resin B | mmol | g | Resin C | mmol | g |
|---|---|---|---|---|---|---|
| Diamine | Bis-APAF | 312.50 | 114.46 | Bis-APAF | 265.63 | 97.29 |
| | | | | TFMB | 46.88 | 15.01 |
| Anhydride | ODPA | 237.50 | 73.67 | ODPA | 293.75 | 91.12 |
| | 6FDA | 59.38 | 26.38 | | | |
| End Capper | PA | 31.25 | 6.00 | PA | 37.50 | 7.20 |
| Solvent | PGMEA | | 500 | PGMEA | | 500 |

| | | | | |
|---|---|---|---|---|
| GPC | Mw | 7,800 | Mw | 7,500 |
| | PDI | 1.94 | PDI | 1.87 |
| IR | DOI | 94.20% | DOI | 89.70% |

In Table 1, Bis-APAF is 2,2-bis(3-amino-4-hydroxyphenyl)hexafluoropropane, ODPA is bis(3,4-dicarboxyphenyl)ether dianhydride, 6FDA is 4,4′-(hexafluoroisopropylidene)diphthalic anhydride, PA is phthalic anhydride, PGMEA is propylene glycol monomethyl ether acetate, TFMB is 2,2′-bis(trifluoromethyl)benzidine, Mw is a weight average molecular weight, and PDI means molecular weight distribution.

<Preparation of Resins B1 and B2>

The polymerized Resin B solution was stirred at room temperature. Acryloyloxyethyl isocyanate (2-isocyanatoethyl acrylate, AOI, CAS 13641-96-8) was added in 20 mol % and 40 mol % based on a total equivalent of 100 mol % of 2,2-bis(3-amino-4-hydroxyphenyl)hexafluoropropane (Bis-AP-AF) of Resin B. The reactor temperature was raised to 60° C., and the result was stirred for 12 hours to respectively polymerize Resins B1 and B2.

Weight average molecular weights (Mw) of the polymerized Resins B1 and B2 measured through gel permeation chromatography (GPC) were 8,150 g/mol and 8,320 g/mol, and as a result of infrared spectrometer (IR) measurements on Resins B1 and B2, degrees of imidization (DO were 94.40% and 94.30%.

### Examples 1 to 4 and Comparative Examples 1 to 3

Using binder resins A, B, C, A1, A2, B1 and B2 prepared through the preparation examples, and the like, photosensitive resin compositions including alkali-soluble polyimide resins were prepared as Examples 1 to 4, and photosensitive resin compositions not including alkali-soluble polyimide resins were prepared as Comparative Examples to 3 as in the following Table 2.

TABLE 2

| | | | | | | Compara- | Compara- | Compara- |
|---|---|---|---|---|---|---|---|---|
| | | | | | | tive | tive | tive |
| | | Example | Example | Example | Example | Example | Example | Example |
| | | 1 | 2 | 3 | 4 | 1 | 2 | 3 |
| Pigment in | 15% | 24.00% | 24.00% | 24.00% | 24.00% | 24.00% | 24.00% | 24.00% |
| Coloring Agent | | | | | | | | |
| Dispersant in | 3% | 4.80% | 4.80% | 4.80% | 4.80% | 4.80% | 4.80% | 4.80% |
| Coloring Agent | | | | | | | | |
| Binder for | 3% | 4.80% | 4.80% | 4.80% | 4.80% | 4.80% | 4.80% | 4.80% |
| Dispersion in | | | | | | | | |
| Coloring Agent | | | | | | | | |
| Binder Resin | Resin | 15.78% | — | 15.78% | — | 31.57% | — | — |
| | A | | | | | | | |
| | Resin | 23.68% | 31.57% | — | 31.57% | — | — | — |
| | A1 | | | | | | | |
| | Resin | — | 7.89% | — | — | — | — | — |
| | B | | | | | | | |
| | Resin | — | — | 23.68% | — | — | — | — |
| | B1 | | | | | | | |
| | Resin | — | — | — | 7.89% | — | — | — |
| | C | | | | | | | |
| | ACRYL A | — | — | — | — | 7.89% | 7.89% | 31.57% |
| | PHS A | — | — | — | — | — | 31.57% | 7.89% |
| Crosslinking | DPHA | 22.13% | 22.13% | 22.13% | 22.13% | 22.13% | 22.13% | 22.13% |
| Agent | | | | | | | | |
| Surfactant | BYK- | 0.31% | 0.31% | 0.31% | 0.31% | 0.31% | 0.31% | 0.31% |
| | 331 | | | | | | | |
| Photopolymer- | OXE02 | 4.50% | 4.50% | 4.50% | 4.50% | 4.50% | 4.50% | 4.50% |
| ization Initiator | | | | | | | | |
| Solvent (Ratio | PGMEA | 60.00% | 60.00% | 60.00% | 60.00% | 60.00% | 60.00% | 60.00% |
| Except Solid | MEDG | 35.00% | 35.00% | 35.00% | 35.00% | 35.00% | 35.00% | 35.00% |
| Content 100% | GBL | 5.00% | 5.00% | 5.00% | 5.00% | 5.00% | 5.00% | 5.00% |
| Composition | | | | | | | | |
| Ratio) | | | | | | | | |

In Table 2, the coloring agent includes a pigment, a dispersant and a binder for dispersion. Weight ratios of the pigment, the dispersant and the binder for dispersion included in the coloring agent were 15 parts by weight, 3 parts by weight and 3 parts by weight, respectively, with respect to 100 parts by weight of the coloring agent. As the pigment, OBP-1 of BASF Corporation was used, and as a solvent for preparing the coloring agent, propylene glycol monomethyl ether acetate (PGMEA) was used. As the dispersant and the binder for dispersion included in the coloring agent, the same resin as the binder resin used in each of Examples 1 to 4 and Comparative Examples 1 to 3 was used. Specifically, as the dispersant and the binder for dispersion of Example 1, the binder resin used in Example 1 (polymer compound obtained by mixing Resin A and Resin A1 in 15.78 parts by weight:23.68 parts by weight, respectively) was used, and the dispersant and the binder for dispersion were used in 4.80 parts by weight and 4.80 parts by weight, respectively, with respect to 100 parts by weight of a solid content of the photosensitive resin composition. As another example, as the dispersant and the binder for dispersion of Example 2, the binder resin used in Example 2 (polymer compound obtained by mixing Resin B and Resin A1 in 7.89 parts by weight:31.57 parts by weight, respectively) was used, and the dispersant and the binder for dispersion were used in 4.80 parts by weight and 4.80 parts by weight, respectively, with respect to 100 parts by weight of a solid content of the photosensitive resin composition. The dispersants and the binders for dispersion of Examples 3 and 4 were also selected and used in a similar manner to the dispersants and the binders for dispersion of Examples 1 and 2. As the dispersant and the binder for dispersion of Comparative Example 1, the binder resin used in Comparative Example 1 (polymer compound obtained by mixing Resin A and ACRYL A in 31.57 parts by weight:7.89 parts by weight, respectively) was used, and the dispersant and the binder for dispersion were used in 4.80 parts by weight and 4.80 parts by weight, respectively, with respect to 100 parts by weight of a solid content of the photosensitive resin composition. As another example, as the dispersant and the binder for dispersion of Comparative Example 2, the binder resin used in Comparative Example 2 (polymer compound obtained by mixing ACRYL A and PHS A in 7.89 parts by weight:31.57 parts by weight, respectively) was used, and the dispersant and the binder for dispersion were used in 4.80 parts by weight and 4.80 parts by weight, respectively, with respect to 100 parts by weight of a solid content of the photosensitive resin composition. The dispersant and the binder for dispersion of Comparative Example 3 were also selected and used in a similar manner to the dispersants and the binders for dispersion of Comparative Examples 1 and 2.

ACRYL A of Table 2 is an acrylic resin including repeating units represented by the following Structural Formulae A-1 to A-3.

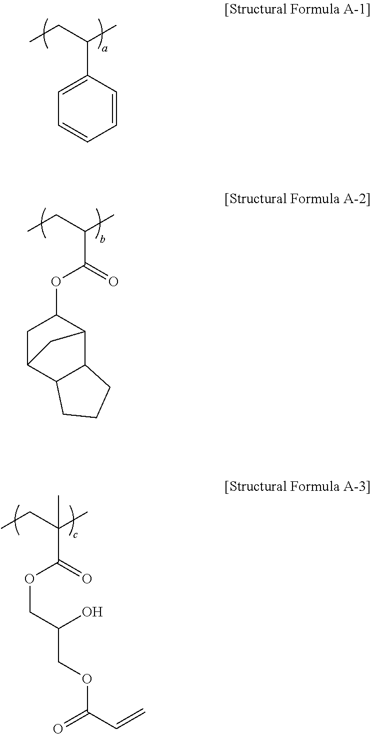

In Structural Formulae A-1 to A-3 included in ACRYL A of Table 2, a:b:c is 0.55:0.25:0.20.

ACRYL A has a molecular weight of 13,000 g/mol.

PHS A of Table 2 is an acrylic resin including repeating units represented by the following Structural Formulae A-4 and A-5.

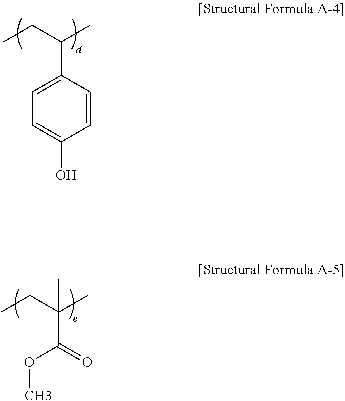

In Structural Formulae A-4 and A-5 included in PHS A of Table 2, d:e is 0.4:0.6.

PHS A has a molecular weight of 8,000 g/mol.

In addition, in Table 2, DPHA is diphenylpentaerythritol hexaacrylate, BYK-331 is a dispersant (surfactant) of BYK-Chemie GmbH, OXE02 is a photopolymerization initiator of BASF Corporation, MEDG is diethylene glycol methyl ethyl ether, and GBL is gamma butyrolactone.

### Experimental Example

Evaluation of Out-Gas and Heat Resistance

For the photosensitive resin compositions of Examples 1 to 4 and the photosensitive resin compositions not including the alkali-soluble polyimide resin of Comparative Examples 1 to 3, out-gas and heat resistance were measured using the following methods, and the results are shown in the following Table 4.

Out-Gas Measurement

1. Method of Preparing Sample for Out-Gas Measurement

The composition was coated on a 100 mm×100 mm×0.5 T glass substrate and spin coated, and an RPM rate was set so that the cured film has a thickness of 1.0 μm after a final curing process. The coated substrate was under vacuum at 45 Pa in a vacuum chamber dryer (VCD) to remove the solvent. The substrate was heated on a 100° C. hot plate for 120 seconds to remove the solvent. The negative composition was exposed to 50 mJ using an exposure device. The exposed surface was exposed to a developing solution for 120 seconds. The substrate was cured for 30 minutes in a 230° C. convection oven.

2. Method of Measuring Out-Gas

The prepared sample was cut into a size of 10 mm×70 mm, and the corresponding sample was introduced to a PAT tube. A material generated while heating the sample for 30 minutes at a temperature of 230° C. was purged & trapped through a purge & trap sampler, and analyzed by P&T GC/MS. The resulting value is ng/cm² obtained through calculating an area with respect to a toluene standard solution, and is expressed as an absolute value, however, relative comparisons were made since the values may vary depending on the sample or equipment condition. The amount of out-gas obtained from the analysis is described in the following Table 3.

Heat Resistance Measurement

The coated surface of the prepared sample was scraped off with a knife, and analyzed using a thermogravimetric analysis (TGA) method. An inflection point was measured while raising the temperature from 25° C. that is room temperature to 450° C. at a temperature raising rate of 10° C. under the nitrogen atmosphere. The measured inflection point values are described in the following Table 3.

TABLE 3

| | | Exam- | Exam- | Exam- | Exam- | Comparative | Comparative | Comparative |
|---|---|---|---|---|---|---|---|---|
| | | ple 1 | ple 2 | ple 3 | ple 4 | Example 1 | Example 2 | Example 3 |
| Out-gas | ng/cm² | 23 | 33 | 31 | 30 | 94 | 113 | 221 |
| Measured Heat | ° C. | 363 | 362 | 362 | 368 | 324 | 296 | 275 |
| Resistance Value | | | | | | | | |
| (Td5%) | | | | | | | | |

As seen from Table 3, the photosensitive resin composition according to one embodiment of the present disclosure has a reduced amount of out-gas generated compared to the photosensitive resin composition not according to the present disclosure. Specifically, the amounts of out-gas generated according to Examples 1 to 4 were from 23 ng/cm² to 33 ng/cm², which are smaller than 94 ng/cm² to 221 ng/cm², the amounts of out-gas generated according to Comparative Examples 1 to 3. Particularly, according to Example 1 and Comparative Example 3, the amount of out-gas generated of the photosensitive resin composition including the alkali-soluble polyimide resin according to one embodiment of the present disclosure decreased by up to approximately 89.59% compared to the amount of out-gas generated of the photosensitive resin composition not including the alkali-soluble polyimide resin, and the effect of significantly reducing the amount of out-gas generated was identified.

As seen from Table 3, the photosensitive resin composition according to one embodiment of the present disclosure has superior heat resistance compared to the photosensitive resin composition not according to the present disclosure. Specifically, the measured heat resistance values according to Examples 1 to 4 were from 362° C. to 368° C., which are higher than 324° C., 296° C. or 275° C., the measured heat resistance values according to Comparative Examples 1 to 3. Particularly, according to Example 4 and Comparative Example 3, the heat resistance of the photosensitive resin composition including the alkali-soluble polyimide resin according to one embodiment of the present disclosure increased by up to approximately 33.82% compared to the heat resistance of the photosensitive resin composition not including the alkali-soluble polyimide resin, and having superior heat resistance was identified.

1. A photosensitive resin composition comprising:
an alkali-soluble polyimide resin including repeating units represented by the following Chemical Formulae 1 to 3; and
a solvent: 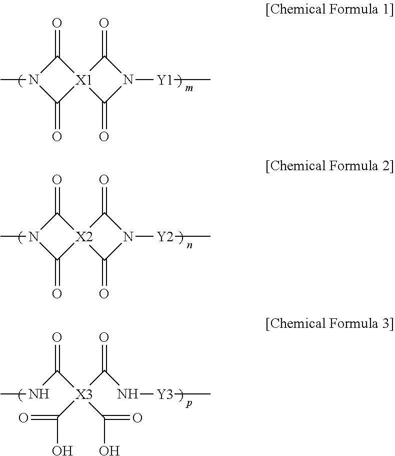
wherein, in the Chemical Formulae 1 to 3,
X1 to X3 are the same as or different from each other, and each independently a tetravalent organic group;
Y1 to Y3 are the same as or different from each other, and each independently a divalent organic group; and
Y2 includes a group represented by the following Chemical Formula A, 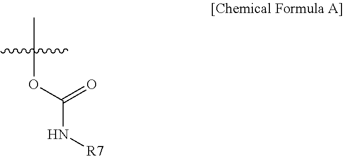
in the Chemical Formula A,
R7 is hydrogen; deuterium; a hydroxyl group; a halogen group; a nitro group; a nitrile group; a substituted or unsubstituted alkyl group; a substituted or unsubstituted alkenyl group; a substituted or unsubstituted alkynyl group; a substituted or unsubstituted alkoxy group; a substituted or unsubstituted aryloxy group; a substituted or unsubstituted cycloalkyl group; a substituted or unsubstituted aryl group; a substituted or unsubstituted heterocyclic group; or a photopolymerizable unsaturated group; 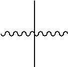
means a site bonding to Y2 of the Chemical Formula 2; and
m to p are each independently an integer of 1 to 500.

2. The photosensitive resin composition of claim 1, comprising at least one of a binder resin; and a coloring agent,
wherein the at least one of the binder resin and the coloring agent includes the alkali-soluble polyimide resin.

3. The photosensitive resin composition of claim 1 comprising:
a binder resin; and
a coloring agent,
wherein the binder resin and the coloring agent include the alkali-soluble polyimide resin.

4. The photosensitive resin composition of claim 3, comprising:
the binder resin in 15 parts by weight to 50 parts by weight; and
the coloring agent in 14 parts by weight to 50 parts by weight,
with respect to 100 parts by weight of a solid content of the photosensitive resin composition.

5. The photosensitive resin composition of claim 2, wherein the coloring agent includes a pigment; and at least one of a dispersant and a binder for dispersion.

6. The photosensitive resin composition of claim 5, wherein the at least one of the dispersant and the binder for dispersion includes the alkali-soluble polyimide resin.

7. The photosensitive resin composition of claim 3, wherein the coloring agent includes a pigment, a dispersant and a binder for dispersion, and the dispersant and the binder for dispersion include the alkali-soluble polyimide resin.

8. The photosensitive resin composition of claim 7, wherein,
a content of the pigment is from 10 parts by weight to 40 parts by weight;
a content of the dispersant is from 2 parts by weight to 15 parts by weight; and
a content of the binder for dispersion is from 2 parts by weight to 15 parts by weight,
with respect to 100 parts by weight of a solid content of the photosensitive resin composition.

9. The photosensitive resin composition of claim 1, wherein X1 to X3 are the same as or different from each other, and each independently a tetravalent organic group derived from oxydiphthalic anhydride or a derivative thereof.

10. The photosensitive resin composition of claim 1, wherein Y1 to Y3 are the same as or different from each other, and each independently a divalent organic group including a hydroxyl group, a phenolic hydroxyl group or a haloalkyl group.

11. The photosensitive resin composition of claim 1, wherein R7 is a photopolymerizable unsaturated group.

12. The photosensitive resin composition of claim 1, wherein, as for m to p of the Chemical Formulae 1 to 3, p/(m+n+p) is from 0.03 to 0.15.

13. The photosensitive resin composition of claim 1, wherein the alkali-soluble polyimide resin has a weight average molecular weight of 1,000 g/mol to 35,000 g/mol.

14. The photosensitive resin composition of claim 1, further comprising:
a multifunctional monomer;
a crosslinking agent;
a photopolymerization initiator;
a surfactant; and
a silane coupling agent.

15. The photosensitive resin composition of claim 14, comprising:
the multifunctional monomer in 1 parts by weight to 40 parts by weight;
the crosslinking agent in 0.1 parts by weight to 40 parts by weight;
the photopolymerization initiator in 0.1 parts by weight to 10 parts by weight;
the surfactant in 0.1 parts by weight to 5 parts by weight; and
the silane coupling agent in 0.1 parts by weight to 2 parts by weight,
with respect to 100 parts by weight of a solid content of the photosensitive resin composition.

16. The photosensitive resin composition of claim 14, wherein a content of an alkali-soluble hydroxyl group of the alkali-soluble polyimide resin is from 30 parts by weight to 85 parts by weight with respect to 100 parts by weight of the multifunctional monomer.

17. A photosensitive material comprising the photosensitive resin composition of claim.

18. A black matrix comprising the photosensitive resin composition of claim 1.

19. An electronic device comprising the photosensitive resin composition of claim 1.
